(19) United States
(12) Patent Application Publication
(10) Pub. No.: US 2006/0108677 A1
(43) Pub. Date: May 25, 2006

(54) Multi-chip package and method of fabricating the same

(76) Inventors: Mitsutaka Ikeda, Kawasaki-shi (JP); Katsuhito Kikuma, Tokyo (JP); Sachiko Nogami, Kawasaki-shi (JP); Yuji Akashi, Kani-shi (JP)

Correspondence Address: Paul J. Winters, 307 Cypress Point Drive, Mountain View, CA, 94043, US

(21) Appl. No.: 11/261,174

(22) Filed: Oct. 28, 2005

Related U.S. Application Data
(63) Continuation of application No. PCT/JP04/16117, filed on Oct. 29, 2004.

(51) Int. Cl. H01L 23/02; H01L 21/50

(52) U.S. Cl. 257/686; 438/109; 257/E23.085

(57) ABSTRACT

A lower chip is fixed to a surface of an interposer by flip-chip bonding with an under fill acting as an adhesive applied to the surface. A lifted pad having a height of approximately 10 μm is provided on the surface of the interposer. A bonding wire connects the lifted pad and a bonding pad provided on a surface of an upper chip. A stick-out portion of the under fill at the time of fixing the lower chip to the interposer is dammed by the lifted portion of the lifted pad. This prevents the stick-out portion of the under fill from covering the top of the lifted pad.

### CROSS REFERENCE TO RELATED APPLICATIONS

This is a continuation of International Application No. PCT/JP2004/016117, filed Oct. 29, 2004.

### BACKGROUND OF THE INVENTION

1. Field of the Invention

The present invention relates to a multi-chip package having a laminated package structure and a method of fabricating the same.

2. Description of the Related Art

Recently, there have been increasing demands for downsizing of mobile communication equipment and electronic components, which are, for example, non-volatile memories like IC memory cards. There have been considerable activities in the development of realizing the downsized electronic components by reducing the number of structural parts used in the electronic components or miniaturizing these structural parts. An essential technique for meeting the above demands is the mounting technique for packaging a semiconductor chip that is an essential component efficiently (with a high integration density). Particularly, it is considered that the technique of multiple semiconductor chips on a system substrate having a limited area by packaging the chips in a stacked fashion has a great prospect.

SMCP (Stacked Multi-Chip Package) is known as the technique of mounting multiple semiconductor chips with the stacked structure (see, for example, Japanese Patent Application Publication No. 11-297927). In the SMCP, multiple chips are stacked on an interposer (MCP substrate) and are mounted in a single package. However, the SMCP has a limited combination of mountable chips in the single chip and a limited number of chips that can be stacked. Therefore, the SMCP is fabricated by FWS-MCP (Flip Wire Stacked MCP) or WFS-MCP (Wire Flip Stacked MCP), which are the combination of various mounting techniques such as the wire bonding and the flip-chip mounting.

The wire bonding is the basic mounting technique for electrically connecting pads on the chip to those on the interposer by a wire bonder. The wire bonding is less expensive but is not capable of stacking chips having an identical size. The flip-chip mounting is the technique for facedown-mounting the chip having bumps provided on pads and joining the chip with an under fill. The flip-chip mounting is applied to only the lowermost chip, but has an advantage of stacking chips having an identical size above the flip chip by utilizing the wire bonding technique.

FIG. 1 is a diagram showing a disadvantage caused at the time of mounting stacked chips by the combination of the flip-chip mounting and the wire bonding. In FIG. 1, there is illustrated an SMCP in which a lower chip 12 and an upper chip 13 are stacked and mounted on a main surface of an interposer 11. Solder balls 14 are provided on the backside of the interposer 11 in a ball grid array. The lower chip 12 is fixed to the interposer 11 with an under fill 15 of liquid acting an adhesive applied to the main surface of the interposer 11. Bumps 17 provided on the backside of the lower chip 12 and pads 18 provided on the main surface of the interposer 11 are electrically connected by the flip-chip bonding. Bonding wires 20 are used to connect bonding pads 16 provided on the main surface of the upper chip 13 and pads 19 provided on the surface of the interposer 11.

In the flip-chip mounting with the under fill 15 of liquid, if the under fill 15 is not applied to the pads 18 on which the bumps 17 are provided, a foreign material may intrude into the uncoated area and may cause a failure such as debonding of the chip. It is thus essentially required to coat the main surface of the interposer 11 with the under fill 15 so as to go round the entire backside of the lower chip 12. However, as shown in FIG. 1, the pads 19 are provided on the interposer 11 of the SMCP in addition to the pads for the flip-chip mounting. Thus, there is a possibility that the pads 19 may be coated with the liquid under fill 15 that sticks out the backside of the lower chip 12 when the lower chip 12 is fixed to the interposer 11. This coating prevents the bonding wires 20 from making electrical connections between the bonding pads 16 on the upper chip 13 and the pads 19 on the interposer 11. A “bank forming method” directed to solving the above problems is known.

FIG. 2 shows the bank forming method. In order to avoid the coating of the pads 19 for wire bonding caused by the “sticking-out” under fill 15, a “bank” 21 made of, for example, resist is provided so as to be interposed between the pads 19 and the chip mounting area and have a height of tens of μm. The under fill 15 that sticks out the backside of the lower chip 12 when the lower chip 12 is fixed to the interposer 11 is dammed by the bank 21, so that the coating of the pads 19 for wire bonding caused by the stick-out under fill 15 can be avoided.

However, the use of the bank 21 needs the additional space (generally, 1 mm wide) for formation and increases the package size. Thus, the bank 21 prevents the required downsizing.

### SUMMARY OF THE INVENTION

The present invention has been made taking the above into consideration and has an object of realizing SMCP using wire bonding in which the coating of pads for wire bonding with an under fill can be avoided without increasing the package size.

This object of the present invention is achieved by a multi-chip package including: an interposer having bonding pads; and a stack of semiconductor chips attached to the interposer by an adhesive, the bonding pads being connected to the stack by wires and having a height not covered by the adhesive. The multi-chip package may be configured so that: a lowermost semiconductor chip of the stack is flip-chip mounted on the interposer; and the bonding pads are connected to an uppermost semiconductor chip of the stack by the wires. The multi-chip package may be configured so that each of the bonding pads has an insulator, and a conductive pad member provided on the insulator. The multi-chip package may be configured so that the each of the bonding pads includes a metal member provided on an interconnection line provided on the interposer. The multi-chip package may be configured so that the bonding pads include bumps provided on interconnection lines provided on the interposer. The multi-chip package may be configured so that the bonding pads include gold bumps provided on interconnection lines provided on the interposer. The multi-chip package may be configured so that each of the bonding pads has an insulator and a conductor provided on the insulator, and the conductor is part of an interconnection line on the interposer. The multi-chip package may be configured so that the adhesive covers the interconnection line except a portion thereof located on the insulator. The multi-chip package may be configured so that the adhesive contacts at least lower portions of the bonding pads.

The present invention also includes a method of fabricating a multi-chip package comprising the steps of: providing insulators on an interposer; forming interconnections lines having portions that cover the insulators, the portions serving as bonding pads; and attaching a stack of semiconductor chips to the interposer by an adhesive provided on the interposer. The method may further include a step of bonding wires between electrodes of the stack and the portions of the interconnection lines on the insulators.

The present invention also includes a method of fabricating a multi-chip package comprising the steps of: forming interconnection lines on an interposer; providing conductive members on the interconnection lines, the conductive members having a given height; and attaching a stack of semiconductor chips to the interposer by an adhesive provided on the interposer. The method may be configured so that the step of attaching uses the adhesive that is in a liquid state.

According to the present invention, it is possible to provide the SMCP using wire bonding in which the coating of pads for wire bonding with the under fill can be avoided without increasing the package size.

### BRIEF DESCRIPTION OF THE DRAWINGS

FIG. 1 is a diagram showing a problem caused when stacked chips are mounted using the combination of flip-chip mounting and wire bonding;

FIG. 2 is a diagram of a bank forming method;

FIG. 3 is a diagram of a structure of an SMCP according to an aspect of the present invention;

FIG. 4 is a diagram of a process of fabricating an SMCP according to a first embodiment;

FIG. 5 is a diagram of a process of fabricating an SMCP according to a second embodiment; and

FIG. 6 is a diagram of a process of fabricating an SMCP according to a third embodiment.

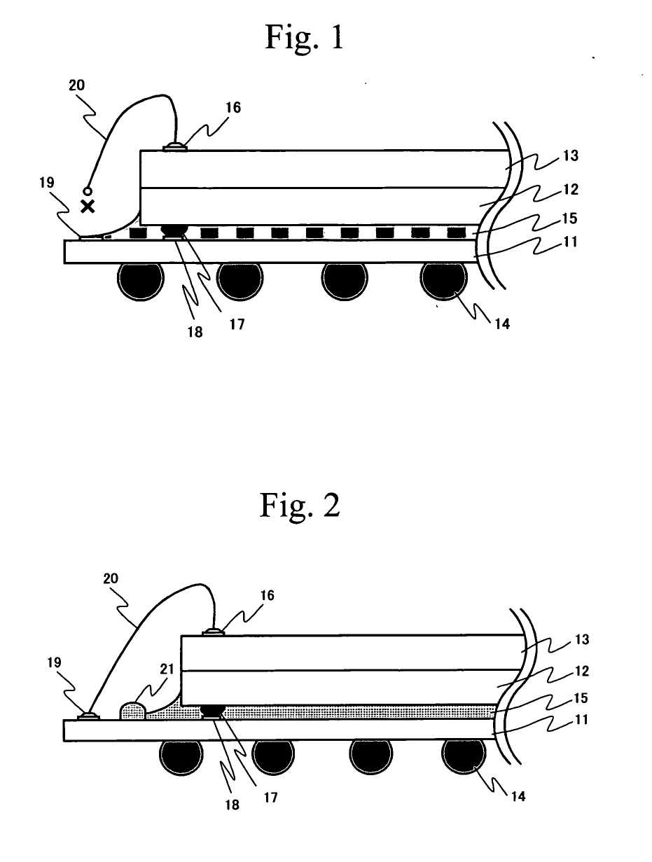

### DESCRIPTION OF THE PREFERRED EMBODIMENTS

A description will now be given, with reference to the accompanying drawings, of embodiments of the present invention.

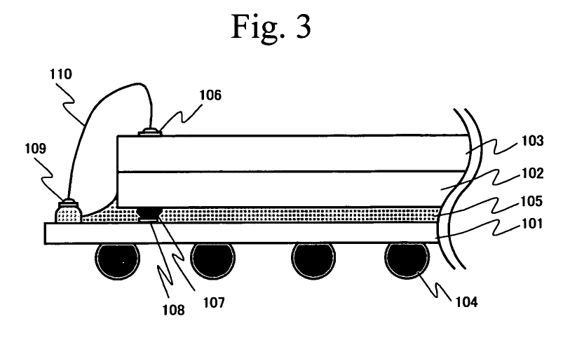

FIG. 3 is a diagram of a structure of an SMCP according to an aspect of the present invention, and shows a part of the SMCP in which a lower chip 102 and an upper chip are stacked and mounted on the main surface of an interposer 101. Solder balls 104 are provided on the backside of the interposer 101. The lower chip 102 is fixed to the main surface of the interposer 101 with an under fill 105 being used as an adhesive, in which the under fill 105 is thermoset synthetic resin in a liquid state and is coated on the surface of the interposer 101. Flip-chip bonding is used to electrically connect bumps 107 provided on the backside of the lower chip 102 and pads 108 provided on the surface of the interposer 101. Lifted pads 109 for wire bonding are provided on the surface of the interposer 101 so as to have height of, for example, 10 μm. Bonding wires 110 are used to connect the lifted pads 109 and the bonding pads 106 on the main surface of the upper chip 103.

In the present SMCP, the pads for wire bonding on the interposer 101 are the lifted pads 109. The lifted portions of the lifted pads 109 function to dam the under fill 105 that sticks out the backside of the lower chip 102 when the lower chip 102 is fixed to the interposer 101 and to prevent the top portions of the lifted pads 109 from being coated with the stick-out under fill 105. The use of the lifted pads 109 does not need the additional area specifically used to dam the stick-out under fill, but certainly makes the connections between the bonding pads 106 on the upper chip 103 and the lifted pads 109 on the interposer 101 by wire bonding. In this manner, the coating of pads for wire bonding with the under fill can be avoided without increasing the package size, so that the downsized SMCP can be realized with the combination of flip-chip bonding and wire bonding. The lifted pads 109 may have an arbitrary structure as long as the lifted pads 109 function to dam the stick-out under fill and have pads for wire bonding on the tops thereof. Some structures of the lifted pads 109 will be described below in connection with some embodiments.

The present SMCP and the multi-chip module (MCM) disclosed in Japanese Patent Application Publication No. 11-297927 may be similar to each other in the following limited viewpoint. That is, the present SMCP and the multi-chip module do not need the specific space for damming the stick-out under fill when the bonding pads 106 on the upper chip 103 are bonded the lifted pads 109 for wire bonding on the interposer 101. However, the MCM described in Japanese Patent Application Publication No. 11-297927 proposes an arrangement in which the pads for wire bonding for the upper chip are provided on a sub substrate specifically provided for the upper chip. In contrast, the present SMCP does not need the sub substrate but uses the single substrate on which the upper and lower chips are mounted. That is, Japanese Patent Application Publication No. 11-297927 employs multiple sub substrates respectively for mounting multiple chips, and forms the MCM by stacking the multiple sub substrates. Thus, the fabrication process of the MCM needs an additional step of stacking the sub substrates in addition to the process of stacking the chips. In contrast, the present invention employs an arrangement such that the upper chip 103 and the lower chip 102 are mounted on the interposer 101 provided common thereto, and needs only the stacking process for the chips. Thus, the fabrication process is greatly simplified.

Several embodiments of the present invention will now be described.

### First Embodiment

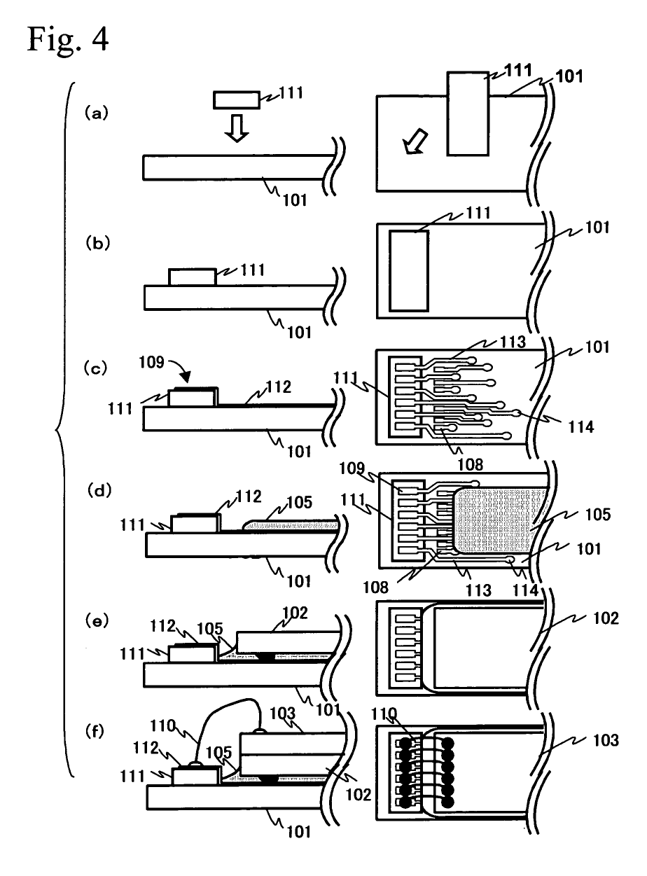

FIG. 4 is a diagram of a process for fabricating the SMCP according to a first embodiment. In each of parts (a) through (f) of FIG. 4, the left figure shows a schematic cross section, and the right figure shows a schematic top view. First, the interposer 101 that is a substrate for wiring on the SMCP and an attachment 111 made of an insulator are prepared (FIG. 4(a)). Next, the attachment 111 if fixed to an outer peripheral region on the interposer 101 in given positions with thermoset resin or the like (FIG. 4(b)). The dimensions of the attachment 111 are a parameter that is appropriately adjustable. For example, the attachment 111 is 50 μm high. FIG. 4(b) shows only the attachment 111 provided in the vicinity of the left-side edge of the interposer 110. However, in practice, an appropriate number of multiple attachments 111 having appropriate dimensions is arranged on the interposer 101 in bonding positions associated with the bonding pads on the upper chip 103.

After the attachment 111 is fixed, an interconnection layer 112 is formed on the main surface of the interposer 101. The interconnection layer 112 may be formed by a general process such as etching, electrolytic plating or electroless plating. This process results in the pads 108 for flip-chip mounting on the main surface of the interposer 101 and interconnection lines 113. When the interposer 101 is a multilayered substrate, through holes 114 are formed. The pad for wire bonding is formed on the main surface (and a sidewall) of the attachment 111. The attachment 111 and the pad for wire bonding formed on the top thereof form the lifted pad 109.

Subsequent to the forming of the interconnection layer 112, the under fill 105 is applied so as not to cover the surface of the lifted pad 109 (FIG. 4(d)), and the lower chip 102 is mounted so that the pad 108 for flip-chip bonding on the interposer 101 and the bump 107 on the back surface of the lower chip 102 are electrically connected (FIG. 4(e)). At that time, the lower chip 102 is pressed against the interposer 101. This causes the under fill 105 to spread over the ends of the back surface of the lower chip 102 and go round. For example, the under fill 105 may stick out and come close to the side surface of the lifted pad 109. However, the lifted pad 109 has a sufficient height (for example, 50 μm) and prevents the top of the lifted pad 109 from being covered.

The upper chip 103 is stacked on the lower chip 102 fixed to the interposer 101 in the above-mentioned process, and the bonding pad 106 on the upper chip 103 is connected to the lifted pad 109 by the bonding wire 110 (FIG. 4(f)). Then, the stacked chips are sealed with resin, and not-shown solder balls are attached to the back surface of the interposer 101, so that the SMCP can be completed.

### Second Embodiment

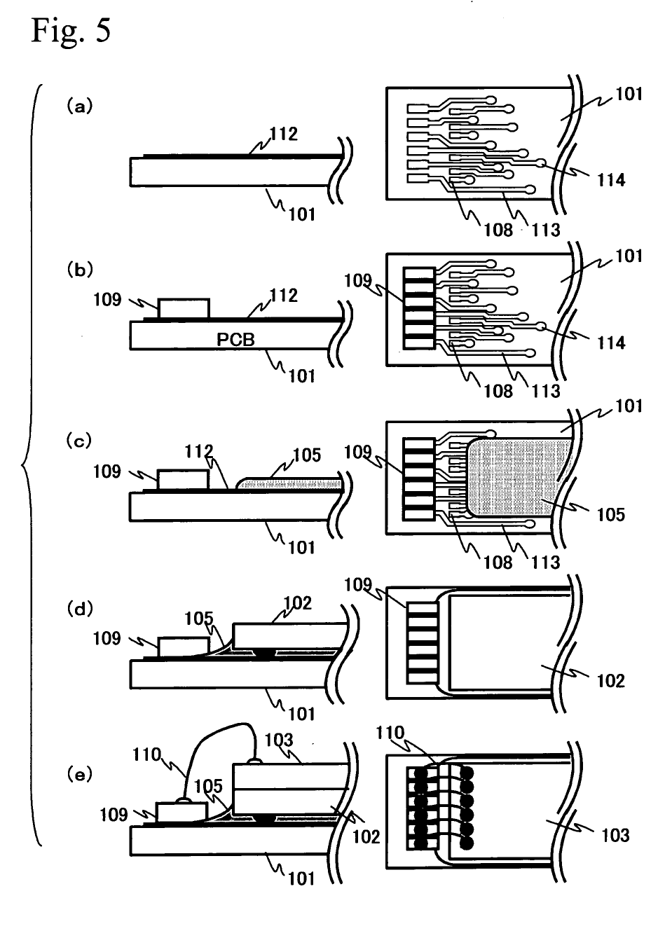

FIG. 5 is a diagram of a process for fabricating the SMCP according to a second embodiment. In each of parts (a) through (e) of FIG. 5, the left figure shows a schematic cross section, and the right figure shows a schematic top view. The interconnection layer 112 is formed on the main surface of the interposer 101, which is the substrate for interconnections of the SMCP. The interconnection layer 112 may be formed by a general process such as etching, electrolytic plating or electroless plating. This process results in the pads 108 for flip-chip mounting on the main surface of the interposer 101, the interconnection lines 113, and pads for wire bonding in given positions close to the peripheral edges of the interposer 101 (FIG. 5(a)).

Next, the lifted pad 109 made of an electrically conductive substance such as Cu is bonded to each bonding pad in the peripheral regions on the interposer 101 by a conductive paste adhesive or ultrasonic welding (FIG. 5(b)). It is noted that FIG. 5(b) shows only the lifted pad 109 provided close to the left edge of the interposer 101, but, in practice, an appropriate number of multiple lifted pads 109 having appropriate dimensions is arranged on the interposer 101 in bonding positions associated with the bonding pads on the upper chip 103.

Subsequently, the under fill 105 is applied so as not to cover the surface of the lifted pad 109 (FIG. 5(c)), and the lower chip 102 is mounted so that the pad 108 for flip-chip bonding on the interposer 101 and the bump 107 on the back surface of the lower chip 102 are electrically connected (FIG. 5(d)). At that time, the lower chip 102 is pressed against the interposer 101. This causes the under fill 105 to spread over the ends of the back surface of the lower chip 102 and go round. For example, the under fill 105 may stick out and come close to the side surface of the lifted pad 109. However, the lifted pad 109 has a sufficient height (for example, 50 μm) and prevents the top of the lifted pad 109 from being covered.

The upper chip 103 is stacked on the lower chip 102 fixed to the interposer 101 in the above-mentioned process, and the bonding pad 106 on the upper chip 103 is connected to the lifted pad 109 by the bonding wire 110 (FIG. 5(e)). Then, the stacked chips are sealed with resin, and not-shown solder balls are attached to the back surface of the interposer 101, so that the SMCP can be completed.

### Third Embodiment

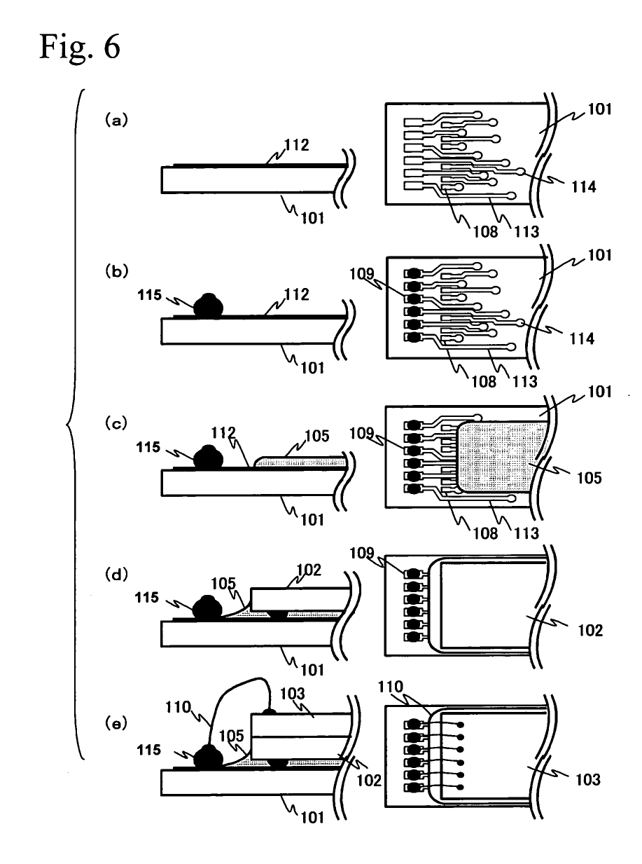

FIG. 6 is a diagram of a process for fabricating the SMCP according to a second embodiment. In each of parts (a) through (e) of FIG. 6, the left figure shows a schematic cross section, and the right figure shows a schematic top view. The interconnection layer 112 is formed on the main surface of the interposer 101, which is the substrate for interconnections of the SMCP. The interconnection layer 112 may be formed by a general process such as etching, electrolytic plating or electroless plating. This process results in the pads 108 for flip-chip mounting on the main surface of the interposer 101, the interconnection lines 113, and pads for wire bonding in given positions close to the peripheral edges of the interposer 101 (FIG. 6(a)).

Next, an Au bump 115 acting as the lifted pad 109 is bonded to each bonding pad in the peripheral regions on the interposer 101 by an ordinary ball banding method (FIG. 6(b)). It is noted that FIG. 6(b) shows only the Au bump 115 provided close to the left edge of the interposer 101, but, in practice, an appropriate number of multiple Au bumps 115 having appropriate dimensions is arranged on the interposer 101 in bonding positions associated with the bonding pads on the upper chip 103.

Subsequently, the under fill 105 is applied so as not to cover the surface of the Au bumps 115 (FIG. 6(c)), and the lower chip 102 is mounted so that the pad 108 for flip-chip bonding on the interposer 101 and the bump 107 on the back surface of the lower chip 102 are electrically connected (FIG. 6(d)). At that time, the lower chip 102 is pressed against the interposer 101. This causes the under fill 105 to spread over the ends of the back surface of the lower chip 102 and go round. For example, the under fill 105 may stick out and come close to the side surface of the Au bumps 115. However, the Au bump 115 has a sufficient height (for example, 50 μm) and prevents the top of the Au bump 115 from being covered.

The upper chip 103 is stacked on the lower chip 102 fixed to the interposer 101 in the above-mentioned process, and the bonding pad 106 on the upper chip 103 is connected to the Au bump 115 by the bonding wire 110 (FIG. 6(e)). Then, the stacked chips are sealed with resin, and not-shown solder balls are attached to the back surface of the interposer 101, so that the SMCP can be completed.

According to the present invention, it is possible to provide the SMCP using wire bonding in which the coating of pads for wire bonding with the under fill can be avoided without increasing the package size.

What is claimed is:

1. A multi-chip package comprising:
an interposer having bonding pads; and
a stack of semiconductor chips attached to the interposer by an adhesive,
the bonding pads being connected to the stack by wires and having a height not covered by the adhesive.

2. The multi-chip package as claimed in claim 1, wherein:
a lowermost semiconductor chip of the stack is flip-chip mounted on the interposer; and
the bonding pads are connected to an uppermost semiconductor chip of the stack by the wires.

3. The multi-chip package as claimed in claim 1, wherein each of the bonding pads has an insulator, and a conductive pad member provided on the insulator.

4. The multi-chip package as claimed in claim 1, wherein the each of the bonding pads includes a metal member provided on an interconnection line provided on the interposer.

5. The multi-chip package as claimed in claim 1, wherein the bonding pads include bumps provided on interconnection lines provided on the interposer.

6. The multi-chip package as claimed in claim 1, wherein the bonding pads include gold bumps provided on interconnection lines provided on the interposer.

7. The multi-chip package as claimed in claim 1, wherein the each of the bonding pads has an insulator and a conductor provided on the insulator, and the conductor is part of an interconnection line on the interposer.

8. The multi-chip package as claimed in claim 7, wherein the adhesive covers the interconnection line except a portion thereof located on the insulator.

9. The multi-chip package as claimed in claim 1, wherein the adhesive contacts at least lower portions of the bonding pads.

10. A method of fabricating a multi-chip package comprising the steps of:
providing insulators on an interposer;
forming interconnections lines having portions that cover the insulators, the portions serving as bonding pads; and
attaching a stack of semiconductor chips to the interposer by an adhesive provided on the interposer.

11. The method as claimed in claim 10, further comprising a step of bonding wires between electrodes of the stack and the portions of the interconnection lines on the insulators.

12. A method of fabricating a multi-chip package comprising the steps of:
forming interconnection lines on an interposer;
providing conductive members on the interconnection lines, the conductive members having a given height; and
attaching a stack of semiconductor chips to the interposer by an adhesive provided on the interposer.

13. The method as claimed in claim 10, wherein the step of attaching uses the adhesive that is in a liquid state.
